(19) United States
(12) Patent Application Publication
(10) Pub. No.: US 2015/0167160 A1
(43) Pub. Date: Jun. 18, 2015

(54) ENABLING RADICAL-BASED DEPOSITION OF DIELECTRIC FILMS

(71) Applicant: Applied Materials, Inc., Santa Clara, CA (US)

(72) Inventors: Yihong CHEN, San Jose, CA (US); Shaunak MUKHERJEE, Santa Clara, CA (US); Amit CHATTERJEE, Cupertino, CA (US); Pramit MANNA, Santa Clara, CA (US); Abhijit Basu MALLICK, Fremont, CA (US); Ningli LIU, Cupertino, CA (US); Jianhua ZHOU, Campbell, CA (US); Juan Carlos ROCHA-ALVAREZ, San Carlos, CA (US); Mukund SRINIVASAN, Fremont, CA (US)

(21) Appl. No.: 14/270,216

(22) Filed: May 5, 2014

Related U.S. Application Data
(60) Provisional application No. 61/930,737, filed on Jan. 23, 2014.
(60) Provisional application No. 61/916,503, filed on Dec. 16, 2013.

(51) Int. Cl. C23C 16/452

(52) U.S. Cl. CPC C23C 16/452

(57) ABSTRACT

One or more precursor gases, such as one or more silicon-containing gases, which may be one or more organosilicon and/or tetraalkyl orthosilicate gases, are introduced into a processing chamber and exposed to radicals. Dielectric films deposited using the techniques disclosed herein may contain silicon. The deposited films may exhibit few defects, low shrinkage, and high etch selectivity, mechanical stability, and thermal stability. The deposition conditions can be very mild, so damage to the substrate and the as-deposited films from UV radiation and ion bombardment is minimal or nonexistent.

### CROSS-REFERENCE TO RELATED APPLICATIONS

This application claims priority to U.S. Provisional Patent Application Ser. No. 61/916,503, filed on Dec. 16, 2013, and to U.S. Provisional Patent Application Ser. No. 61/930,737, filed on Jan. 23, 2014, which herein are incorporated by reference.

### BACKGROUND

1. Field

Embodiments disclosed herein generally relate to the development of dielectric films, and more specifically to the development of silicon-containing dielectric films.

2. Description of the Related Art

The formation of dielectric films, such as amorphous silicon-containing dielectric films, under damage-free conditions is desirable for developing next-generation electronic devices. Current techniques for depositing amorphous silicon-containing dielectric films expose the deposited film to damaging effects, such as charged-particle bombardment and high-energy ultraviolet irradiation. As device components decrease in size, they become increasingly sensitive to such damaging effects.

Therefore, there is a need in the art for forming dielectric films under damage-free conditions.

### SUMMARY

Embodiments disclosed herein include a method for forming dielectric films under damage-free conditions. The method includes introducing into a processing chamber one or more precursor gases. The precursor gases may be silicon-containing precursor gases, for example organosilicon and/or tetraalkyl orthosilicate gases. One or more of argon and helium is also introduced into the processing chamber, and the one or more precursor gases are exposed to radicals. The radicals may be hydrogen radicals, hydroxyl radicals, nitrogen radicals, NH radicals, and/or oxygen radicals.

Films formed according to embodiments disclosed herein may be, as compared to currently used techniques of forming silicon-containing dielectric films, exposed to significantly fewer film damaging effects, such as charged-particle bombardment and high-energy ultraviolet irradiation. The reduction of film-damaging effect is important because next-generation devices are especially sensitive to such effects.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a processing chamber suitable for forming a dielectric film, such as a silicon-containing dielectric film, according to one embodiment.

### DETAILED DESCRIPTION

The descriptions of the various embodiments are presented for illustrative purposes and are not intended to be exhaustive or limiting. Many modifications and variations will be apparent to those of ordinary skill in the art without departing from the scope and spirit of the described embodiments. The terminology used herein was chosen to best explain the principles of the embodiments, the practical applications or technical improvements over technologies found in the marketplace, or to enable others of ordinary skill in the art to understand the embodiments disclosed herein.

Embodiments disclosed herein generally provide methods of forming dielectric films, such as silicon-containing dielectric films. More specifically, precursor gases are introduced into a processing chamber and are thereafter exposed to radicals to form a dielectric material. The precursor gases may contain silicon. For example, the precursor gases may be one or more organosilicons or tetraalkyl othosilicates. The radicals may include hydrogen radicals, hydroxyl radicals, nitrogen radicals, NH radicals, oxygen radicals, and mixtures thereof. The processing chamber may be, for example, a vacuum sealed chamber containing a radical source or coupled to a radical source. The radical source may be, for example, a remote plasma source or the filament of a hot wire chemical vapor deposition (HW-CVD) chamber. A remote plasma source refers to a region coupled to a processing chamber in which a plasma is generated and that is spatially separated from the region of the processing chamber in which deposition occurs. At least one surface of the processing chamber that contacts the generated radicals may be composed at least in part of materials that are substantially unreactive with the generated radicals in order to maximize the radical flux at the deposition surface.

The methods disclosed herein offer advantages, such as the following. The use of a radical source produces growth conditions that are substantially or completely free of film-damaging effects, such as charged-particle bombardment and high-energy ultraviolet irradiation, which often occur in conventional techniques and which next generation devices are particularly susceptible to. Additionally, the generated radicals abstract hydrogen from the Si—H, C—H, and N—H bonds of the precursors, allowing for, at a given temperature, the deposition of films having a lower hydrogen content than conventional techniques. Silicon-containing dielectric films formed using the methods disclosed herein exhibit, as compared to currently used methods of forming silicon-containing dielectric films, significantly fewer defects, significantly lower shrinkage, and significantly better etch selectivity, mechanical stability, and thermal stability. Moreover, films deposited according to the methods disclosed herein offer greater conformality than conventional plasma enhanced chemical vapor deposition (PECVD) techniques. Although not to be limited by theory, it is believed that the improved conformality is related to the inability of plasma, which is limited by the thickness of the plasma sheath, to extend to the bottom of very deep trenches. Radicals can diffuse into and react with precursors in deep trenches much more readily. The aforementioned advantages are illustrative and not limiting. It is not necessary for all embodiments of the invention to have all the advantages of the invention or fulfill all the purposes of the invention.

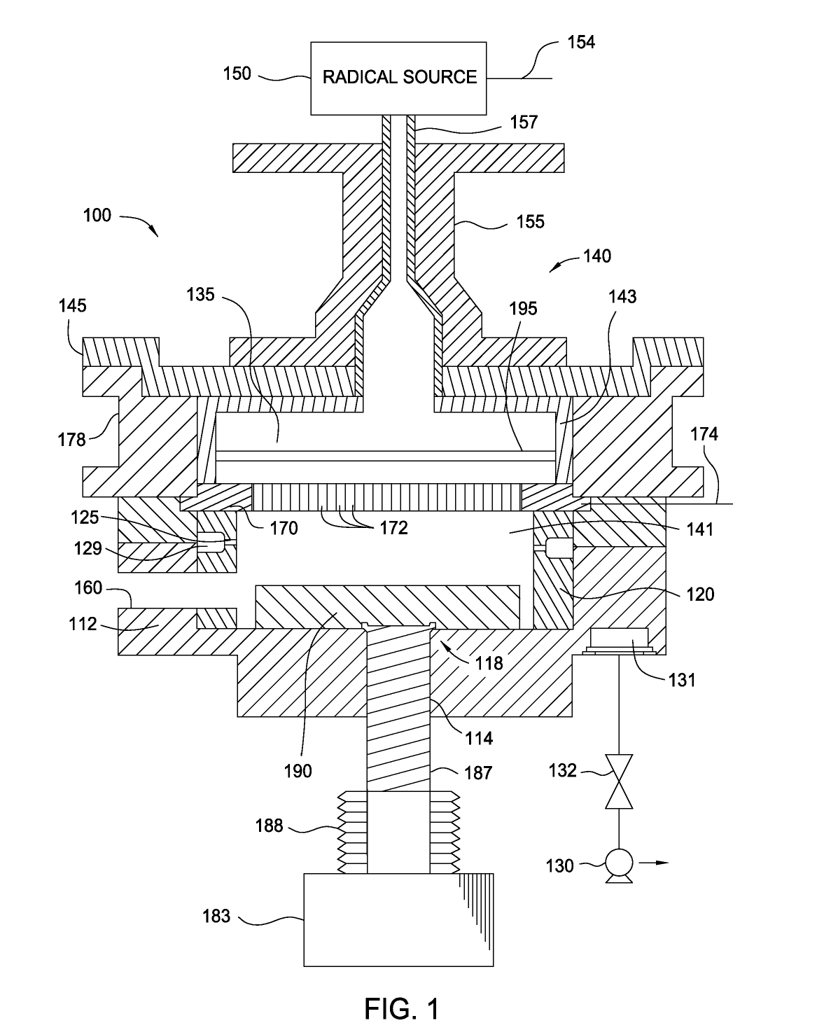

FIG. 1 is a schematic cross-sectional view of one processing chamber suitable for practicing the methods disclosed herein. Many other processing chambers may be used to practice the disclosed embodiments. In one embodiment, the processing chamber 100 includes a chamber body 112, a lid assembly 140, and a support assembly 118. The lid assembly 140 is disposed at an upper end of the chamber body 112, and the support assembly 118 is at least partially disposed within the chamber body 112. The processing chamber 100 is coupled to a radical source 150.

The chamber body 112 includes a slit valve opening 160 formed in a sidewall thereof to provide access to the interior of the processing chamber 100. The slit valve opening 160 is selectively opened and closed to allow access to the interior of the chamber body 112. The chamber body 112 may include a liner 120 that surrounds the support assembly 118. The liner 120 may include one or more apertures 125 and a pumping channel 129 formed therein that is in fluid communication with a vacuum system. The apertures 125 provide a flow path for gases into the pumping channel 129, which provides an egress for the gases within the processing chamber 100.

The vacuum system can include a vacuum pump 130 and a throttle valve 132 to regulate flow of gases through the processing chamber 100. The vacuum pump 130 is coupled to a vacuum port 131 disposed on the chamber body 112 and therefore, in fluid communication with the pumping channel 129 formed within the liner 120. The apertures 125 allow the pumping channel 129 to be in fluid communication with a processing zone 141 within the chamber body 112. The processing zone 141 is defined by a lower surface of the gas distribution plate 170 and an upper surface of the support assembly 118, and is surrounded by the liner 120.

The support assembly 118 can include a support member 190 to support a substrate (not shown) for processing within the chamber body 112. The substrate may be any standard wafer size, such as, for example, 300 mm. Alternatively, the substrate may be larger than 300 mm. The support member 190 can be coupled to a lift mechanism 183 through a shaft 187 which extends through a centrally-located opening 114 formed in a bottom surface of the chamber body 112. The lift mechanism 183 can be flexibly sealed to the chamber body 112 by a bellows 188 that prevents vacuum leakage from around the shaft 187. The lift mechanism 183 allows the support member 190 to be moved vertically within the chamber body 112 between a process position and a lower, transfer position. The transfer position is slightly below the opening of the slit valve 160 formed in a sidewall of the chamber body 112. During operation, the spacing between the substrate and the gas distribution plate 170 may be minimized in order to maximize radical flux at the substrate surface. For example, the spacing may be between about 100 mil and about 5,000 mil. The support member 190 may also contain a heater (not shown).

The lid assembly 140 includes radical source 150, radical conduit 157, top plate 145, lid rim 178, radical cavity 135, and gas distribution plate 170. Radicals are generated in the radical source 150 and then travel through the radical conduit 157 into the radical cavity 135, where the radicals then pass through the gas distribution plate 170 and into the processing zone 141.

Optionally, an ion filter 195 may be disposed in the radical cavity 135. The ion filter 195 removes the ions, electrons, and ultraviolet radiation generated in the plasma in order to maximize radical generation and prevent damage to the deposited film. Ion filter 195 can also control the number of radicals that pass through. Also optionally, the chamber and chamber component surfaces that contact the radicals may be composed at least in part of a material that is substantially unreactive to radicals. By not consuming the generated radicals, the coating increases the radical flux to the substrate.

The radical source 150 is positioned at the top of the lid assembly 140 and is coupled on one end to radical conduit 157 and on another end to a first one or more gas inlets 154 (only one is shown). One or more process gases, which may be radical-forming gases, may enter the radical source 150 via the first one or more gas inlets 154. The first one or more gas inlets 154 are coupled on another end to one or more upstream gas sources and/or other gas delivery components, such as gas mixers. For example, the first one or more gas inlets 154 may be coupled at the second end to upstream sources of hydrogen, oxygen, H₂O, nitrogen, argon, helium, and/or ammonia that may be used to generate radicals in the radical source 150. Radical source 150 may be coupled directly to radical conduit 157 (as shown) or indirectly through a second radical conduit or other suitable means.

The radical source 150 generates radicals that are used to deposit dielectric films, such as silicon-containing dielectric films. The radical source 150 may be, for example, a remote plasma source. The remote plasma source may be a capacitively coupled plasma (CCP) source, an inductively coupled plasma (ICP) source, a microwave induced (MW) plasma source, an electron cyclotron resonance (ECR) chamber, or a high density plasma (HDP) chamber. In an alternative embodiment using a different chamber configuration, the radical source may be the filament of a hot wire chemical vapor deposition (HW-CVD) chamber. MW and ECR sources have the highest H₂ disassociation efficiency among common plasma sources. ICP sources have lower disassociation efficiency, which makes deposition of high quality films more difficult. Radicals generated in the radical source 150 travel into the radical conduit 157.

Radical conduit 157 is coupled on one end to the radical source 150 and on the other end to the radical cavity 135. Radical conduit 157 is disposed within and supported by radical conduit support member 155. Radical conduit support member 155 is mounted to top plate 145, and top plate 145 rests on lid rim 178.

Radical conduit 157 may be composed at least in part of a material that is substantially unreactive to radicals. For example, radical conduit 157 may be composed of anodized Al₂O₃; sapphire; AlN; SiO₂; Y₂O₃; MgO; ceramics containing one or more of Al₂O₃, sapphire, AlN, Y₂O₃, MgO; or plastics. A representative example of a suitable SiO₂ material is quartz. Alternatively or additionally, radical conduit 157 may have a coating on the surface that contacts the radicals in operation. The coating may also include anodized Al₂O₃; sapphire; AlN; SiO₂; Y₂O₃; MgO; ceramics containing one or more of Al₂O₃, sapphire, AlN, Y₂O₃, MgO; or plastics. If a coating is used, the thickness of the coating may be between about 1 μm and about 1 mm. The coating may be applied using a spray coating process.

Radical cavity 135 is positioned below and coupled to radical conduit 157. Radical cavity 135 is bounded by a ceiling, sidewalls, and gas distribution plate 170. Optionally, the radical cavity 135 may include a liner 143. The liner 143 may cover the sidewalls and/or the ceiling. The surfaces of radical cavity 135 that contact radicals, including the ceiling, sidewalls, surfaces of liner 143, and the top surface of the gas distribution plate 170, may be composed of or coated with a material that is substantially unreactive to radicals. For example, the surfaces may be composed of or coated with anodized Al₂O₃; sapphire; AlN; SiO₂; Y₂O₃; MgO; ceramics containing one or more of Al₂O₃, sapphire, AlN, Y₂O₃, MgO; or plastics. A representative example of a suitable SiO₂ material is quartz. If a coating is used, the thickness of the coating may be between about 1 μm and about 1 mm.

Gas distribution plate 170 is positioned between the radical cavity 135 and the processing zone 141. Gas distribution plate 170 may be a dual channel shower head. Gas distribution plate 170 may include second one or more gas inlets 174 (only one is shown) that are at least partially formed within gas distribution plate 170. The second one or more gas inlets 174 are in fluid communication with at least some of the plurality of apertures 172 of gas distribution plate 170 at a first end thereof and coupled to one or more gas sources and/or other gas delivery components, such as gas mixers, at a second end thereof. For example, the second one or more gas inlets 174 may be coupled at the second end to one or more sources of precursor gases selected to form dielectric films in processing zone 141.

Gas distribution plate 170 may include a plurality of apertures 172. Apertures 172 are passageways that distribute the flow of gases therethrough. Apertures 172 can be sized and positioned about gas distribution plate 170 to provide a controlled and even flow distribution to the processing zone 141. The apertures 172 prevent the gas(es) from impinging directly on the substrate surface by slowing and re-directing the velocity profile of the flowing gases, as well as evenly distributing the flow of gas to provide an even distribution of gas across the surface of the substrate. The apertures 172 are configured so that a first one or more gases from the first one or more gas inlets 154 and the radicals generated by the radical source 150 can pass through a first set of apertures, a second one or more gases from the second one or more gas inlets 174 can pass through a second set of apertures, and the first one or more gases and radicals and the second one or more gases are not in communication with each other while disposed within the apertures.

The bottom surface and the surfaces surrounding the apertures 172 of the gas distribution plate 170 may also be coated with a material that is substantially unreactive to radicals. For example, the coating may include anodized Al₂O₃; sapphire; AlN; SiO₂; Y₂O₃; MgO; ceramics containing one or more of Al₂O₃, sapphire, AlN, Y₂O₃, MgO; or plastics. A representative example of a suitable SiO₂ material is quartz. The coating thickness may be between about 1 μm and about 1 mm.

The method of forming the dielectric films, such as silicon-containing dielectric films, is described as follows. At least one radical-forming gas and optionally one or more carrier gases are introduced into the radical source 150 of the processing chamber 100 from the first one or more gas inlets 154. At least one precursor gas is introduced into the processing zone 141 from the second one or more gas inlets 174. Radicals are generated in the radical source 150 and are introduced into the processing zones 141 to deposit a dielectric film. The radicals are supplied until a film of the desired thickness is obtained.

The radical-forming gases that may be introduced into the radical source 150 include H₂, H₂O, N₂, O₂, NH₃, and mixtures thereof. For example, the radical-forming gas may be a mixture of H₂ and N₂. Alternatively, the radical-forming gas may be a mixture of H₂ and O₂. In another embodiment, the radical-forming gas may be a mixture of H₂, N₂, and O₂. In another alternative embodiment, the mixture of radical-forming gases may comprise NH₃ and H₂. The radicals may include hydrogen radicals, hydroxyl radicals, nitrogen radicals, NH radicals, oxygen radicals, and mixtures thereof. Hydrogen radicals can be generated from H₂, a mixture of H₂ and NH₃, a mixture of H₂ and O₂, a mixture of H₂ and H₂O, and/or a mixture of H₂ and N₂. Hydroxyl radicals can be generated from H₂O, a mixture of O₂ and H₂, and/or a mixture of H₂ and H₂O. Nitrogen radicals can be generated from a mixture of H₂ and N₂ Nitrogen and NH radicals may be generated from NH₃ and/or a mixture of NH₃ and H₂. Oxygen radicals can be generated from O₂ and/or a mixture of H₂ and O₂. Optionally, carrier gases may be included along with radical-forming gases. Representative carrier gases include argon and helium.

The one or more precursor gases that may be introduced into the processing zone 141 include one or more silicon-containing gases. For example, the one or more precursor gases may include organosilicon, tetraalkyl orthosilicate gases, or disiloxane. Organosilicon gases include gases of organic compounds having at least one carbon-silicon bond. Tetraalkyl orthosilicate gases include gases consisting of four alkyl groups attached to an SiO₄⁴⁻ ion. More particularly, the one or more precursor gases may be (dimethylsilyl)(trimethylsilyl)methane ((Me)₃SiCH₂SiH(Me)₂); hexamethyldisilane ((Me)₃SiSi(Me)₃); trimethylsilane ((Me)₃SiH); tetramethylsilane ((Me)₄Si); tetraethoxysilane ((EtO)₄Si); tetramethoxysilane ((MeO)₄Si); tetrakis-(trimethylsilyl)silane ((Me₃Si)₄Si); (dimethylamino)dimethylsilane ((Me₂N)SiHMe₂); dimethyldiethoxysilane ((EtO)₂Si(Me)₂); dimethyldimethoxysilane ((MeO)₂Si(Me)₂); methyltrimethoxysilane ((MeO)₃Si(Me)); dimethoxytetramethyl-disiloxane (((Me)₂Si(OMe))₂O); tris(dimethylamino)silane ((Me₂N)₃SiH); bis(dimethylamino)methylsilane ((Me₂N)₂CH₃SiH); disiloxane ((SiH₃)₂O); and combinations thereof.

The processing conditions and radical generation conditions during deposition using processing chamber 100 may be as follows. The temperature of processing chamber 100 may be maintained between about 100° C. and 800° C., such as between about 100° C. and 300° C. The pressure of the processing chamber 100 may be maintained between about 10 mTorr and about 20 Torr, such as between about 0.5 Torr and about 8 Torr. The at least one silicon-containing precursor gas may be introduced into the processing zone 141 at a flow rate ranging from about 0.1 sccm to about 10,000 sccm for a 300 mm substrate. The radical-forming gases may be introduced into the radical source 150 at a flow rate ranging from about 1 sccm to about 50,000 sccm for a 300 mm substrate. If used, the flow rate of the carrier gases may range from about 1 sccm to about 50,000 sccm for a 300 mm substrate. Radicals may be generated by the radical source 150. For example, if the radical source 150 is a capacitively coupled remote plasma source, the radicals may be generated from an RF power of between about 50 W and about 10,000 W for a 300 mm substrate, such as an RF power from about 2,000 W to about 15,000 W.

In a representative example of the deposition of a dielectric layer on a 300 mm substrate using processing chamber 100, trisilylamine is introduced into the processing zone 141 at a flow rate of 30 sccm. The radical-forming gases introduced into the radical source 150 include hydrogen and ammonia, which are introduced at flow rates of 5000 sccm and 500 sccm, respectively. Argon is introduced into the radical source 150 as a carrier gas at a flow rate of 5000 sccm. The temperature and pressure of the processing chamber 100 are 200° C. and 1 Torr, respectively. The radical source 150 is a capacitively coupled remote plasma source, and the radicals may be generated from an RF power of 10,000 W. The spacing is 1000 mil. Deposition is carried out for 60 seconds, and the resulting dielectric layer has a thickness of 1000 Å.

The resulting dielectric films may include but are not limited to silicon-containing dielectric films. For example, films may be deposited that are composed of SiC, SiCN, SiO₂, SiOCN, SiON and SiN. The composition of the films depends on the composition of the precursor gases. SiC films may be deposited, for example, by using (dimethylsilyl)(trimethylsilyl)methane, hexamethyldisilane, and/or trimethylsilane. SiCN films may be deposited, for example, by using tris(dimethylamino)silane, bis(dimethylamino)methylsilane, and/or (dimethylamino)dimethylsilane. SiO₂ may be deposited, for example, by using disiloxane. SiOCN films can be formed, for example, by using tris(dimethylamino)silane, bis(dimethylamino)methylsilane, and/or (dimethylamino)dimethylsilane. SiON films can be formed, for example, by using disiloxane or trisilylamine. SiN films may be deposited, for example, by using trisilylamine. The resulting films may be amorphous.

In another embodiment, a material containing Si—H, C—H, and/or N—H bonds is placed inside a processing chamber, such as processing chamber 100. Thereafter, the material may be treated with radicals, such as hydrogen radicals, generated substantially as described above, in order to reduce the number of Si—H, C—H, and N—H bonds.

In summary, silicon-containing precursor gases are introduced into a processing chamber and are thereafter exposed to radicals to form a dielectric material. The radicals create a dielectric film in an environment free of film-damaging effects and abstract hydrogen from the Si—H bonds of the precursors. Dielectric films formed according to the methods disclosed herein exhibit, compared to films formed using conventional methods, significantly fewer defects, significantly lower shrinkage and significantly better etch selectivity, mechanical stability, and thermal stability.

While the foregoing is directed to embodiments of the present invention, other and further embodiments of the invention may be devised without departing from the basic scope thereof, and the scope thereof is determined by the claims that follow.

1. An apparatus, comprising:
a processing chamber;
a silicon-containing precursor gas source coupled to the processing chamber, the silicon-containing precursor gas source configured to introduce into a processing zone of the processing chamber one or more silicon-containing precursor gases;
a radical source coupled to the processing chamber or contained within the processing chamber;
a helium or argon source coupled to the radical source and configured to introduce into the radical source helium or argon; and
wherein the processing chamber is configured to expose the one or more silicon-containing precursor gases to radicals.

2. The apparatus of claim 1, wherein the radicals comprise at least one radical species selected from the group consisting of hydrogen radicals, hydroxyl radicals, nitrogen radicals, NH radicals, and oxygen radicals.

3. The apparatus of claim 2, wherein the one or more silicon-containing precursor gases comprise an organosilicon gas, a tetraalkyl orthosilicate gas, or disiloxane.

4. The apparatus of claim 3, wherein at least one of the one or more silicon-containing precursor gases is selected from the group consisting of (dimethylsilyl)(trimethylsilyl)methane, hexamethyldisilane, trimethylsilane, tetramethylsilane, tetraethoxysilane, tetramethoxysilane, tetrakis(trimethylsilyl)silane, (dimethylamino)dimethylsilane, dimethyldiethoxysilane, dimethyldimethoxysilane, methyltrimethoxysilane, dimethoxytetramethyldisiloxane, tris(dimethylamino)silane, bis(dimethylamino)methylsilane, and disiloxane.

5. The apparatus of claim 4, wherein the radicals comprise nitrogen radicals, hydrogen radicals, and NH radicals.

6. The apparatus of claim 5, wherein the radicals are generated by a remote capacitively coupled plasma source, a remote inductively coupled plasma source, or a HW-CVD chamber.

7. The apparatus of claim 6, wherein at least one surface of the processing chamber that contacts the radicals comprises anodized Al₂O₃; sapphire; AlN; SiO₂; Y₂O₃; MgO; or ceramics containing one or more of Al₂O₃, sapphire, AlN, Y₂O₃, MgO.

8. A method of forming a dielectric film, the method comprising:
introducing into a processing chamber one or more silicon-containing precursor gases;
introducing into the processing chamber one or more of argon and helium; and
exposing the one or more silicon-containing precursor gases to radicals.

9. The method of claim 8, wherein the radicals comprise at least one radical species selected from the group consisting of hydrogen radicals, hydroxyl radicals, nitrogen radicals, NH radicals, and oxygen radicals.

10. The method of claim 9, wherein the one or more silicon-containing precursor gases comprise an organosilicon gas, a tetraalkyl orthosilicate gas, or disiloxane.

11. The method of claim 10, wherein at least one of the one or more silicon-containing precursor gases is selected from the group consisting of (dimethylsilyl)(trimethylsilyl)methane, hexamethyldisilane, trimethylsilane, tetramethylsilane, tetraethoxysilane, tetramethoxysilane, tetrakis(trimethylsilyl)silane, (dimethylamino)dimethylsilane, dimethyldiethoxysilane, dimethyldimethoxysilane, methyltrimethoxysilane, dimethoxytetramethyldisiloxane, tris(dimethylamino)silane, bis(dimethylamino)methylsilane, and disiloxane.

12. The method of claim 11, wherein the radicals comprise nitrogen radicals, hydrogen radicals, and NH radicals.

13. The method of claim 12, wherein the radicals are generated in a remote capacitively coupled plasma source, a remote inductively coupled plasma source, or a HW-CVD chamber.

14. The method of claim 13, wherein at least one surface of the processing chamber that contacts the radicals comprises anodized Al₂O₃; sapphire; AlN; SiO₂; Y₂O₃; MgO; or ceramics containing one or more of Al₂O₃, sapphire, AlN, Y₂O₃, MgO.

15. The method of claim 9, wherein the radicals are generated in a remote capacitively coupled plasma source, a remote inductively coupled plasma source, or a HW-CVD chamber.

16. The method of claim 15, wherein the radicals comprise at least two radical species selected from the group consisting of hydrogen radicals, hydroxyl radicals, nitrogen radicals, NH radicals, and oxygen radicals.

17. The method of claim 16, wherein at least one of the one or more silicon-containing precursor gases is selected from the group consisting of (dimethylsilyl)(trimethylsilyl)methane, hexamethyldisilane, trimethylsilane, tetramethylsilane, tetraethoxysilane, tetramethoxysilane, tetrakis(trimethylsilyl)silane, (dimethylamino)dimethylsilane, dimethyldiethoxysilane, dimethyldimethoxysilane, methyltrimethoxysilane, dimethoxytetramethyldisiloxane, tris(dimethylamino)silane, bis(dimethylamino)methylsilane, and disiloxane.

18. The method of claim 9, wherein at least one surface of the processing chamber that contacts the radicals comprises anodized Al₂O₃; sapphire; AlN; SiO₂; Y₂O₃; MgO; or ceramics containing one or more of Al₂O₃, sapphire, AlN, Y₂O₃, MgO.

19. The method of claim 18, wherein at least one of the one or more silicon-containing precursor gases is selected from the group consisting of (dimethylsilyl)(trimethylsilyl)methane, hexamethyldisilane, trimethylsilane, tetramethylsilane, tetraethoxysilane, tetramethoxysilane, tetrakis(trimethylsilyl)silane, (dimethylamino)dimethylsilane, dimethyldiethoxysilane, dimethyldimethoxysilane, methyltrimethoxysilane, dimethoxytetramethyldisiloxane, tris(dimethylamino)silane, bis(dimethylamino)methylsilane, and disiloxane.

20. A method of forming a dielectric film, the method comprising:
introducing into a processing chamber one or more silicon-containing precursor gases, wherein the one or more silicon-containing precursor gases are selected from the group consisting of ((dimethylsilyl)(trimethylsilyl)methane, hexamethyldisilane, trimethylsilane, tetramethylsilane, tetraethoxysilane, tetramethoxysilane, tetrakis(trimethylsilyl)silane, (dimethylamino)dimethylsilane, dimethyldiethoxysilane, dimethyldimethoxysilane, methyltrimethoxysilane, dimethoxytetramethyldisiloxane, tris(dimethylamino)silane, bis(dimethylamino)methylsilane, and disiloxane;
introducing into the processing chamber one or more of argon and helium; and
exposing the one or more silicon-containing precursor gases to radicals, wherein the radicals comprise at least one radical species selected from the group consisting of hydrogen radicals, hydroxyl radicals, nitrogen radicals, NH radicals, and oxygen radicals, and wherein the radicals are generated in a remote capacitively coupled plasma source, a remote inductively coupled plasma source, or a HW-CVD chamber.
